(19) United States
(12) Patent Application Publication
(10) Pub. No.: US 2022/0326312 A1
(43) Pub. Date: Oct. 13, 2022

(54) LEAKAGE ELECTRIC FIELD MEASUREMENT DEVICE

(71) Applicant: Panasonic Intellectual Property Management Co., Ltd., Osaka (JP)

(72) Inventors: Ryo MATSUBARA, Osaka (JP); Shinichi TANIMOTO, Kyoto (JP)

(73) Assignee: Panasonic Intellectual Property Management Co., Ltd., Osaka (JP)

(21) Appl. No.: 17/637,335

(22) PCT Filed: Aug. 18, 2020
(86) PCT No.: PCT/JP2020/031064

§ 371 Date: Feb. 22, 2022

(30) Foreign Application Priority Data
Aug. 30, 2019 (JP) 2019-159102

(51) Int. Cl. G01R 31/52; G01R 13/02

(52) U.S. Cl. CPC G01R 31/52; G01R 13/0227

(57) ABSTRACT

A leakage electric field measurement device includes a first acquirer that measures a distance to an electric wire, a second acquirer that measures a leakage electric field of the electric wire, a third acquirer that acquires a captured image of the electric wire, and a controller that calculates a predicted value of the leakage electric field of the electric wire on the basis of the distance measured by the first acquirer and the leakage electric field measured by the second acquirer, performs determination of whether or not the electric wire is a live wire according to comparison between an assumed electric field of the electric wire and the predicted value, and generates a composite image in which a result of the determination is superimposed on the captured image acquired by the third acquirer.

### TECHNICAL FIELD

The present disclosure relates to a leakage electric field measurement device.

### BACKGROUND ART

PTL 1 discloses a safety zone checking system that displays and prints out a safety zone for performing maintenance inspection or construction of a plant such as a substation. This safety zone checking system is provided with means for obtaining display and print output in a three-dimensional model of an apparatus in which a charge/power failure state or an operation/stop state of the apparatus is color-coded from an apparatus operation procedure of a plant and apparatus status data and apparatus connection data.

### CITATION LIST

### Patent Literature

PTL 1: Japanese Patent Unexamined Publication No. 10-198877

### SUMMARY OF THE INVENTION

The present disclosure has been made in view of the above circumstances of the related art, and an object thereof is to provide a leakage electric field measurement device visualizing whether or not an electric wire is a live wire.

According to the present disclosure, there is provided a leakage electric field measurement device including a first acquirer that measures a distance to an electric wire; a second acquirer that measures a leakage electric field of the electric wire; a third acquirer that acquires a captured image of the electric wire; and a controller that calculates a predicted value of the leakage electric field of the electric wire on the basis of the distance measured by the first acquirer and the leakage electric field measured by the second acquirer, performs determination of whether or not the electric wire is a live wire according to comparison between an assumed electric field of the electric wire and the predicted value, and generates a composite image in which a result of the determination is superimposed on the captured image acquired by the third acquirer.

According to the present disclosure, it is possible to visualize whether or not an electric wire is a live wire.

### BRIEF DESCRIPTION OF DRAWINGS

FIG. 1 is an appearance diagram illustrating an example of a leakage electric field measurement device (rear surface) according to Exemplary Embodiment 1.

FIG. 2 is an appearance diagram illustrating an example of the leakage electric field measurement device (front surface) according to Exemplary Embodiment 1.

FIG. 3 is a block diagram illustrating an internal configuration example of the leakage electric field measurement device according to Exemplary Embodiment 1.

FIG. 4 is a diagram illustrating an example of an assumed electric field graph.

FIG. 5 is a flowchart illustrating an operation procedure example of the leakage electric field measurement device according to Exemplary Embodiment 1.

FIG. 6A is a diagram illustrating an example of a composite image (live wire).

FIG. 6B is a diagram illustrating an example of a composite image (non-live wire).

FIG. 7 is an appearance diagram illustrating an example of a leakage electric field measurement device (rear surface) according to Exemplary Embodiment 2.

FIG. 8 is an appearance diagram illustrating an example of a leakage electric field measurement device (front surface) according to Exemplary Embodiment 2.

FIG. 9 is a block diagram illustrating an internal configuration example of the leakage electric field measurement device according to Exemplary Embodiment 2.

### DESCRIPTION OF EMBODIMENTS

(Background of Details of Exemplary Embodiment 1)

In the safety zone checking system in PTL 1, there is a probability that a charge/power failure state or an operation/stop state of the apparatus displayed and printed out by the three-dimensional model may not match an actual charge/power failure state or operation/stop state of the apparatus due to an abnormality such as a connection failure of the apparatus. In such a case, it is difficult for a worker (hereinafter, referred to as a user) who performs maintenance inspection or construction of a plant such as a substation to recognize a live wire (energized) state of an electric wire that is a work target, and there is a possibility that an electric shock may occur by performing work in a state in which a work target apparatus is being charged or operated. It is preferable that the user can easily check a live wire (energized) state of an electric wire at the present time, not only during the work, but since an energized state of an apparatus cannot be visually checked, a live wire (energized) state of the electric wire at the present time is not known.

Therefore, in each of the following exemplary embodiments, an example of a leakage electric field measurement device that visualizes whether or not an electric wire is a live wire will be described.

Hereinafter, exemplary embodiments in which a configuration and an operation of the leakage electric field measurement device according to the present disclosure are specifically disclosed will be described in detail with reference to the drawings as appropriate. However, more detailed description than necessary may be omitted. For example, detailed description of already well-known matters and repeated description of substantially the same configuration may be omitted. This is to avoid unnecessary redundancy of the following description and to facilitate the understanding of those skilled in the art. The accompanying drawings and the following description are provided for those skilled in the art to fully understand the present disclosure, and are not intended to limit the subject matter described in the claims.

### Exemplary Embodiment 1

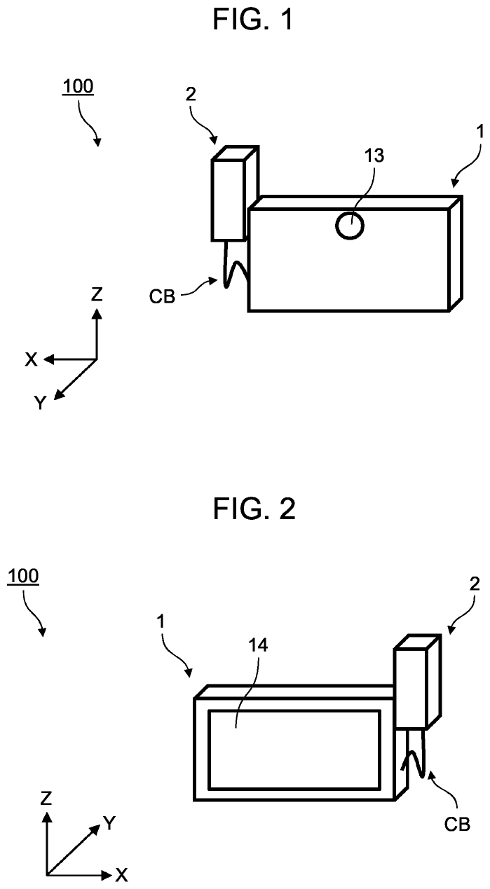

First, an appearance of a leakage electric field measurement device 100 according to Exemplary Embodiment 1 will be described with reference to FIGS. 1 and 2. FIG. 1 is an appearance diagram illustrating an example of the leakage electric field measurement device (rear surface) according to Exemplary Embodiment 1. FIG. 2 is an appearance diagram illustrating an example of the leakage electric field measurement device (front surface) according to Exemplary Embodiment 1. A Y direction illustrated in FIGS. 1 and 2 indicates a front-rear direction of leakage electric field measurement device 100 and terminal device 1, and the rear surface is located in the +Y direction and the front surface is located in the −Y direction. An X direction indicates a longitudinal direction of leakage electric field measurement device 100 and terminal device 1. A Z direction indicates a height direction of leakage electric field measurement device 100 and terminal device 1. The X direction indicates a transverse direction in a case where leakage electric field measurement device 100 and terminal device 1 illustrated in FIGS. 1 and 2 are used in a state of being rotated by 90°.

Leakage electric field measurement device 100 has a configuration in which terminal device 1 such as an augmented reality wearable computer such as a so-called tablet PC, a smartphone, or a smart glass is connected to measurement unit 2 capable of measuring a leakage electric field via a USB (Universal Serial Bus) cable CB in a wired manner. A cable used for connection is not limited to USB cable CB, and may be, for example, a local area network (LAN) cable.

Leakage electric field measurement device 100 includes camera 13 on the rear surface side of terminal device 1 and monitor 14 on the front surface side. Leakage electric field measurement device 100 measures a leakage electric field leaking from a measurement target object (for example, an indoor wiring, and an electric wire used for connection of electrical apparatuses and power transmission and distribution) which is in a live wire (energized) state and to which an AC voltage having a frequency of 50 Hz to 60 Hz is applied, and a distance to the measurement target object, and estimates a voltage value applied to the measurement target object on the basis of the measurement results. Positions of camera 13 and monitor 14 illustrated in FIGS. 1 and 2 are examples, and, for example, in a case where terminal device 1 an augmented reality wearable computer, needless to say, a position thereof is not limited to this.

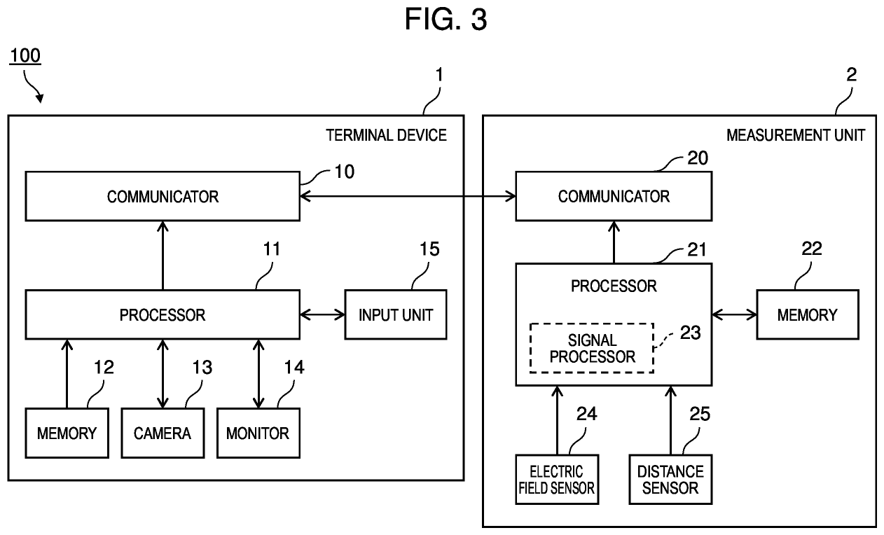

FIG. 3 is a block diagram illustrating an internal configuration example of leakage electric field measurement device 100 according to Exemplary Embodiment 1. Leakage electric field measurement device 100 includes terminal device 1 and measurement unit 2.

First, an internal configuration example of terminal device 1 will be described. Terminal device 1 is configured to include communicator 10, processor 11, memory 12, camera 13, and monitor 14. In a case where terminal device 1 is implemented by an augmented reality wearable computer, camera 13 is not an essential constituent and may thus be omitted, or may be configured separately from terminal device 1 instead of being integrated with terminal device 1. Monitor 14 may be configured separately from terminal device 1 instead of being integrated with terminal device 1. Communicator 10 has a USB connector (not illustrated) or a LAN connector, and is communicatively connected to communicator 20 in measurement unit 2 in a wired manner by using USB cable CB or a LAN cable (not illustrated). Communicator 10 outputs measurement results such as a leakage electric field of the measurement target object and a distance to the measurement target object, received from communicator 20, to processor 11.

In a case where each of electric field sensor 24 and distance sensor 25 of measurement unit 2 is provided separately, communicator 10 may be communicatively connected to each of electric field sensor 24 and distance sensor 25 by using each of a plurality of USB cables (not illustrated).

Communicator 10 may be wirelessly communicatively connected to communicator 20. The wireless communication referred to here is communication via, for example, short-range wireless communication such as Bluetooth (registered trademark) or NFC (registered trademark), or a wireless LAN such as Wifi (registered trademark).

Processor 11 as an example of a controller is configured by using, for example, a central processing unit (CPU), a digital signal processor (DSP), or a field programmable gate array (FPGA), and controls an operation of each constituent of terminal device 1. Processor 11 cooperates with memory 12 to perform various processes and control in an integrated manner. Specifically, processor 11 refers to a program and data stored in memory 12 and executes the program to realize a function of each constituent (for example, a function of estimating a voltage value applied to a measurement target object according to a distance to the measurement target object and a leakage electric field thereof measured, and a function of outputting a composite image in which a measurement result is superimposed on a captured image acquired by camera 13 to monitor 14).

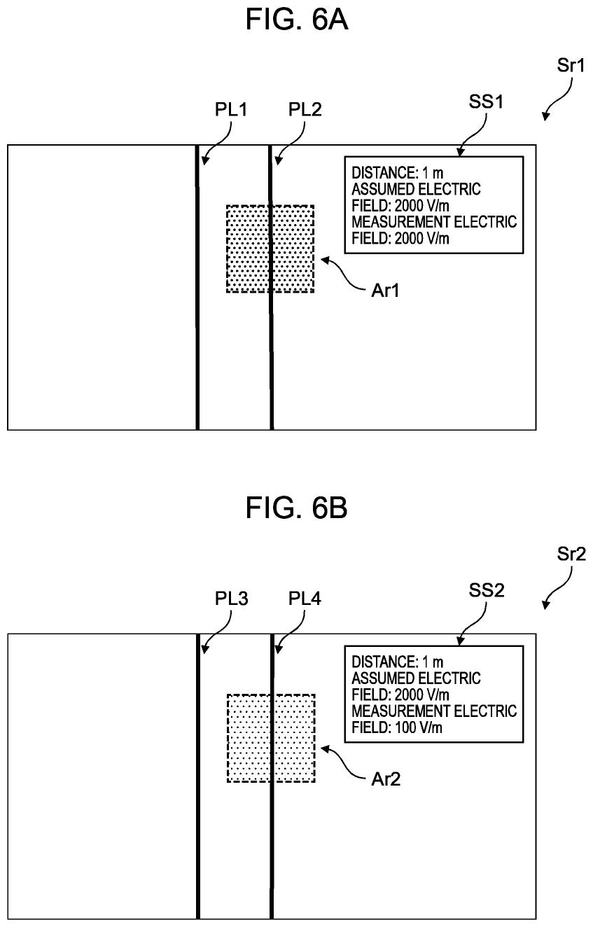

On the basis of a user's input operation, processor 11 receives a predetermined electric field value (hereinafter, referred to as an assumed electric field) such as a nominal voltage or a rated voltage applied to a measurement target object from input unit 15. Processor 11 generates a control signal for starting measurement of a leakage electric field intensity leaking from a measurement target object and a distance to the measurement target object with an input operation for the assumed electric field from input unit 15 or the user's input operation for starting the measurement as a trigger, and transmits the control signal to measurement unit 2. Processor 11 generates a frame line (refer to FIGS. 6A and 6B) indicating a measurement range of each of measurements executed by electric field sensor 24 and distance sensor 25, and superimposes the frame lines on a captured image acquired by camera 13. Each of electric field sensor 24 and distance sensor 25 executes a measurement on a measurement target object located within the frame line.

Here, a method of superimposing a frame line will be described. First, when measurement unit 2 is attached at a predetermined attachment position, processor 11 acquires the attachment position of Measurement unit 2 and a range corresponding to an electric field reception region of electric field sensor 24. Processor 11 generates a frame line indicating the acquired electric field reception region of electric field sensor 24 according to the attachment position of measurement unit 2, and superimposes the frame line on a captured image acquired by camera 13.

Processor 11 receives the leakage electric field intensity of the measurement target object in the frame line measured by electric field sensor 24 (hereinafter, referred to as a measurement electric field) and the distance to the measurement target object measured by distance sensor 25 via communicator 10. Processor 11 receives information regarding the range (coordinates) in which measurement (that is, measurement of the measurement electric field and the distance) is executed by each of electric field sensor 24 and distance sensor 25.

Processor 11 receives a captured image acquired by camera 13. Processor 11 may receive a captured image acquired by distance sensor 25. Processor 11 generates a composite image (refer to FIGS. 6A and 6B) in which the assumed electric field of the measurement target object input by the user, each received measurement result (that is, the measurement electric field and the distance), and the range in which each measurement is executed are superimposed on the captured image acquired by camera 13. Processor 11 outputs the composite image generated by superimposing the assumed electric field, the measurement electric field, the distance, and the frame line on the captured image to monitor 14.

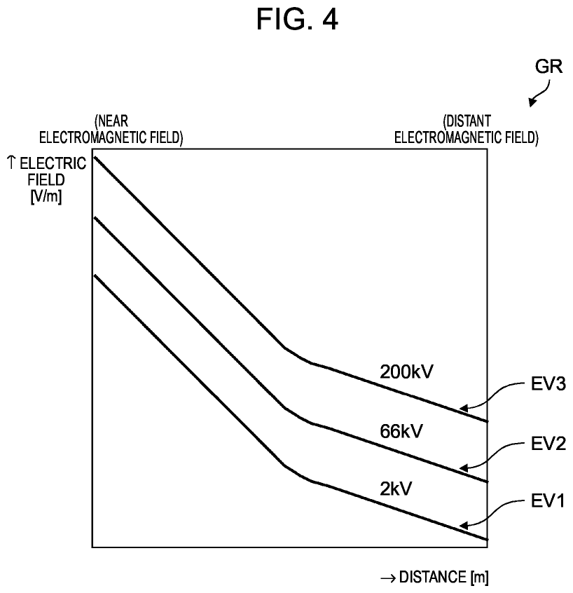

Processor 11 calculates a predicted electric field of the measurement target object on the basis of the leakage electric field of the measurement target object measured by electric field sensor 24 and the distance measured by distance sensor 25. Processor 11 determines whether or not an electric wire that is the measurement target object is a live wire on the basis of an assumed electric field at the distance measured by distance sensor 25 and the calculated predicted electric field by using an assumed electric field graph (refer to FIG. 4) at the assumed electric field (that is, the voltage value of the measurement target object) input by the user.

In a case where a predicted electric field based on each measured measurement result is 70% or more of the assumed electric field, processor 11 determines that the measurement target object is in a live wire (energized) state. Processor 11 generates a notification indicating that the measurement target object is in a live wire (energized) state, and outputs the notification to monitor 14. On the other hand, in a case where the predicted electric field based on each measured measurement result is less than 70% of the assumed electric field, processor 11 determines that the measurement target object is in a non-live wire (non-energized) state. Processor 11 generates a notification indicating that the measurement target object is in a non-live wire (non-energized) state, and outputs the notification to monitor 14. Consequently, leakage electric field measurement device 100 can visualize whether or not an electric wire is a live wire. Here, an example has been described in which the determination of whether or not the electric wire is a live wire is performed on the basis of 70% (predetermined ratio) of the assumed electric field, but an index is not limited to 70%, and may be set as appropriate according to the type of measurement target object or a measurement environment including a positional relationship with other adjacent measurement target objects.

The predicted electric field for determining that the electric wire that is the measurement target object is a live wire is specifically an electric field value that is 70% or more of the assumed electric field (that is, a nominal voltage or a rated voltage). Consequently, in leakage electric field measurement device 100 according to Exemplary Embodiment 1, in a case where there is another generation source of a leakage electric field (for example, an electric wire in a live wire (energized) state) in the vicinity of the measurement target object, even if a leakage electric field leaking from a generation source other than the measurement target object is received by electric field sensor 24, whether or not the measurement target object is a live wire can be determined and visualized.

Processor 11 may estimate a candidate of the assumed electric field on the basis of the measured measurement electric field and distance and the assumed electric field graph (refer to FIG. 4) stored in the memory 12. Processor 11 outputs the estimated candidate of the assumed electric field to monitor 14 and displays the estimated candidate. Specifically, processor 11 determines that an assumed electric field is a candidate of the assumed electric field in a case where the assumed electric field satisfies an electric field value at which the calculated predicted electric field is 70% or more of the assumed electric field, and is equal to or less than an electric field value corresponding to a nominal voltage indicated by the assumed electric field or the maximum voltage with respect to the rated voltage. Consequently, leakage electric field measurement device 100 according to Exemplary Embodiment 1 can estimate an assumed electric field of a measurement target object even in a case where a user does not know the assumed electric field of the measurement target object.

Memory 12 includes, for example, a random access memory (RAM) as a work memory used when each process of processor 11 is executed and a read only memory (ROM) that stores programs and data defining an operation of processor 11. Data or information generated or acquired by processor 11 is temporarily stored in the RAM. A program defining an operation of processor 11 is written in the ROM. The memory 12 stores an assumed electric field graph (refer to FIG. 4), an offset amount between an imaging region of camera 13 and a measurement range of measurement unit 2, and the like.

The memory 12 may store a position (coordinates) of a measurement target object and a voltage value of the measurement target object in association with each other. Consequently, terminal device 1 can acquire the assumed electric field of the measurement target object without an input operation of the user by acquiring the current position information of terminal device 1. In such a case, input unit 15 that will be described later is not an essential constituent and may thus be omitted.

Needless to say, a method of acquiring the assumed electric field is not limited to the above example or the input operation of the user. For example, processor 11 may acquire an assumed electric field of a measurement target object from a substation, a power plant, an electric power company, or the like via communicator 10, and the number, a shape, and the like of porcelains held by a measurement target object that will be described later may be analyzed through an image analysis process of camera 13 to acquire the assumed electric field of the measurement target object.

The offset amount referred to here is a difference between a predetermined position (coordinates) in an imaging region captured by camera 13 and a predetermined position (coordinates) in an electric field reception region measured by measurement unit 2. Specifically, the offset amount is a difference between the reference point in the imaging region of camera 13 (for example, a center point of the imaging region) and the reference point in the electric field reception region of measurement unit 2 (for example, a center point of the electric field reception region). Processor 11 executes a position alignment process of aligning a predetermined position (coordinates) in the electric field reception region with a position (coordinate) corresponding to a predetermined position (coordinate) in the corresponding imaging region on the basis of the offset amount, and generates a composite image in which a frame line indicating an electric field reception region of the leakage electric field in electric field sensor 24 is superimposed. This position alignment process may be realized by, for example, a well-known technique.

Camera 13 as an example of a first acquirer and a third acquirer includes at least a lens (not illustrated) and an image sensor (not illustrated). The image sensor is, for example, a solid-state imaging sensor such as a charged-coupled device (CCD) or a complementary metal oxide semiconductor (CMOS), and converts an optical image formed on an imaging surface into an electric signal.

Camera 13 is provided on the rear surface side of terminal device 1. A position where camera 13 is provided is not limited to the position illustrated in FIG. 1. For example, camera 13 may be provided at the center position on the rear surface side of terminal device 1. Camera 13 outputs the acquired captured image to processor 11.

In a case where distance sensor 25 is omitted, camera 13 measures a distance to a measurement target object. Camera 13 has a so-called autofocus function of executing image analysis and automatically focusing on a predetermined measurement target object captured in the imaging region. Camera 13 automatically focuses on the measurement target object captured in the imaging region, and measures a distance to the measurement target object on the basis of a focal length when the measurement target object is in focus. Camera 13 outputs the acquired captured image and information regarding the measured distance to the measurement target object to processor 11. In a case where the user has designated a measurement target object, camera 13 may execute autofocus on the designated measurement target object.

Monitor 14 as an example of an output unit is configured by using, for example, a liquid crystal display (LCD) or an organic electroluminescence (EL). Monitor 14 displays the captured image acquired by camera 13 or the composite image generated by processor 11.

Monitor 14 may be a touch interface provided in terminal device 1 and configured with a touch panel. In such a case, monitor 14 has a function as an input unit 15, accepts a user's input operation, and outputs a result of the user's input operation to processor 11.

Monitor 14 may be implemented by, for example, a head mounted display (HMD) communicatively connected to terminal device 1 in a wired or wireless manner.

Input unit 15 as an example of a fourth acquirer accepts the user's input operation such as the assumed electric field of the measurement target object or designation of the measurement target object that the user wants to measure, and outputs a result of the input operation to processor 11. Input unit 15 may be realized as the touch panel of monitor 14 described above. Input unit 15 may accept a voice input operation based on the user's voice.

Next, an internal configuration example of measurement unit 2 will be described. Measurement unit 2 measures a leakage electric field leaking from a measurement target object in a live wire (energized) state (for example, an indoor wiring, and an electric wire used for connection to an electrical apparatus or power transmission and distribution) and a distance to the measurement target object. Measurement unit 2 is detachably attached to a predetermined position in terminal device 1. Measurement unit 2 may be attached to a helmet, a belt, or the like equipped by the user. A structure for attaching and detaching measurement unit 2 is not illustrated and description thereof will be omitted.

Measurement unit 2 includes communicator 20, processor 21, memory 22, electric field sensor 24, and distance sensor 25. In a case where a distance to a measurement target object is measured by camera 13 of terminal device 1, distance sensor 25 is not an essential constituent and may thus be omitted. Each of electric field sensor 24 and distance sensor 25 may be configured separately.

Communicator 20 has a USB connector (not illustrated), and is communicatively connected to communicator 10 of terminal device 1 in a wired manner by using USB cable CB. In a case where a LAN cable (not illustrated) is used, communicator 20 may have a USB connector (not illustrated). Communicator 20 transmits, to communicator 10, a measurement voltage measured by electric field sensor 24 and a distance to the measurement target object measured by distance sensor 25.

Communicator 10 may be wirelessly communicatively connected to communicator 20. The wireless communication referred to here is communication via, for example, short-range wireless communication such as Bluetooth (registered trademark) or NFC (registered trademark), or a wireless LAN such as Wifi (registered trademark).

Processor 21 is configured by using, for example, a CPU, a DSP, or an FPGA, and controls an operation of each constituent of measurement unit 2. Each constituent referred to here is, for example, signal processor 23. Processor 21 cooperates with memory 22 to perform various processes and control in an integrated manner. Specifically, processor 21 refers to a program and data stored in memory 22, and executes the program to realize a function of each constituent (for example, a function of converting a reception signal that is received by electric field sensor 24 into a signal indicating a leakage electric field intensity).

Memory 22 has, for example, a RAM as a work memory used when executing each process of processor 21, and a ROM storing a program and data defining an operation of processor 21. Data or information generated or acquired by processor 21 is temporarily stored in the RAM. A program defining an operation of processor 21 is written in the ROM.

Signal processor 23 receives a reception signal intensity from electric field sensor 24. Signal processor 23 performs conversion into a signal indicating the leakage electric field (measurement electric field) leaking from the measurement target object on the basis of the reception signal intensity received from electric field sensor 24. Signal processor 23 outputs a signal indicating the converted leakage electric field (measurement electric field) to communicator 20.

Electric field sensor 24 as an example of a second acquirer has, for example, a dipole antenna or one or a plurality of loop antennas, and is configured to be able to receive an electric field in a frequency bandwidth of 50 Hz to 60 Hz. Electric field sensor 24 may be formed as a planar antenna. Electric field sensor 24 receives an electric field leaking from any of surrounding measurement target objects, and outputs the received reception signal (measurement electric field) to signal processor 23 of processor 21.

A plurality of electric field sensors 24 may be provided instead of one. In such a case, electric field sensor 24 may be a directional antenna. Consequently, it is easy for leakage electric field measurement device 100 to measure a leakage electric field in an electric wire such as a single-phase two-wire system wire or a three-phase three-wire system wire.

Distance sensor 25 as an example of a first acquirer measures a distance to the measurement target object by using, for example, an ultrasonic wave or a radar, and outputs the distance to processor 21. In a case where the user performs an input operation of designating a measurement target object on input unit 15 of terminal device 1, distance sensor 25 measures a distance to the designated measurement target object.

Distance sensor 25 may be, for example, a monocular camera or a stereo camera. In such a case, distance sensor 25 has a function of executing image analysis on an acquired captured image and executing a so-called autofocus process of automatically focusing on a predetermined measurement target object captured in an imaging region. Distance sensor 25 executes the autofocus process on the measurement target object captured in the imaging region, and measures a distance to the measurement target object on the basis of a focal length when the measurement target object is in focus. In a case where the user has designated a measurement target object, distance sensor 25 executes the autofocus process on the designated measurement target object on the basis of a control signal transmitted from processor 11 of terminal device 1 to processor 21 of measurement unit 2.

Next, a relationship between a distance and an assumed electric field will be described with reference to FIG. 4. FIG. 4 is a diagram illustrating an example of assumed electric field graph GR. Assumed electric field graph GR is stored in memory 12.

Assumed electric field graph GR shows transition of a leakage electric field according to a distance to a measurement target object with respect to the leakage electric field leaking from the measurement target object to which a predetermined voltage is applied. Assumed electric field graph GR illustrated in FIG. 4 shows an example of a graph of an electric field leaking from the measurement target object at each of voltages of 2 kV, 66 kV, and 200 kV, but is not limited thereto. For example, assumed electric field graph GR may be a graph of a leakage electric field leaking from a measurement target object to which other voltages (for example, 100V, 200V, 3.3 kV, 22 kV, and 220 kV) are applied, or a graph of a leakage electric field leaking from a measurement target object to which voltages used in each country are applied.

The voltage illustrated in assumed electric field graph GR may be, for example, a phase voltage which is a potential difference between a phase and the ground in a case where the measurement target object is an electric wire of a three-phase three-wire system. In such a case, an assumed electric field input by the user may be a so-called phase voltage. In leakage electric field measurement device 100, in a case where an assumed electric field input by the user is a rated voltage (line voltage) and a phase voltage is desired to be calculated, the phase voltage may be calculated on the basis of a power distribution method (for example, a single-phase two-wire system or a three-phase three-wire system) of the measurement target object. The power distribution method of the measurement target object may be input by the user or may be determined on the basis of a captured image acquired by camera 13.

In a case where a distance is short (small), each of plurality of electric field graphs EV1, EV2, and EV3 illustrated in assumed electric field graph GR comes within a region of a near electromagnetic field and thus an electric field becomes large. On the other hand, in a case where the distance is long (large), each of plurality of electric field graphs EV1, EV2, and EV3 comes within a region of a distant electromagnetic field and thus the electric field becomes small.

The electric field graph EV1 in FIG. 4 is a graph illustrating transition of a leakage electric field according to a distance to the measurement target object (live wire) to which the voltage of 2 kV is applied. The electric field graph EV2 is a graph illustrating transition of a leakage electric field according to the distance to the measurement target object to which the voltage of 66 kV is applied. The electric field graph EV3 is a graph illustrating transition of a leakage electric field according to the distance to the measurement target object (live wire) to which the voltage of 200 kV is applied.

As described above, leakage electric field measurement device 100 according to Exemplary Embodiment 1 can determine whether or not the measurement target object is in a live wire state on the basis of the assumed electric field input by the user, the measurement electric field measured by electric field sensor 24, and the distance measured by distance sensor 25. Leakage electric field measurement device 100 can determine whether or not the measurement target object is in a live wire state on the basis of assumed electric field graph GR, for example, even in a case where the live wire state of the measurement target object is determined from a place far away by a distance longer than the safety isolation distance to a transmission line specified by law in order to prevent an electric accident.

It is needless to say that the safety isolation distance referred to here is an example of a distance in a case where the user uses a high voltage transmission line as a measurement target object, and a distance to the measurement target object is not limited to this. The safety isolation distance is a distance specified by law as a measure to prevent electric shock accidents due to contact with transmission and distribution lines when working with a mobile crane or the like, for example, 2 m at the voltage of 6.6 kV, 3 m at the voltage of 11 kV to 44 kV, 4 m at the voltage of 66 kV to 77 kV, 5 m at the voltage of 154 kV, 7 m at the voltage of 275 kV, and 11 m at the voltage of 500 kV.

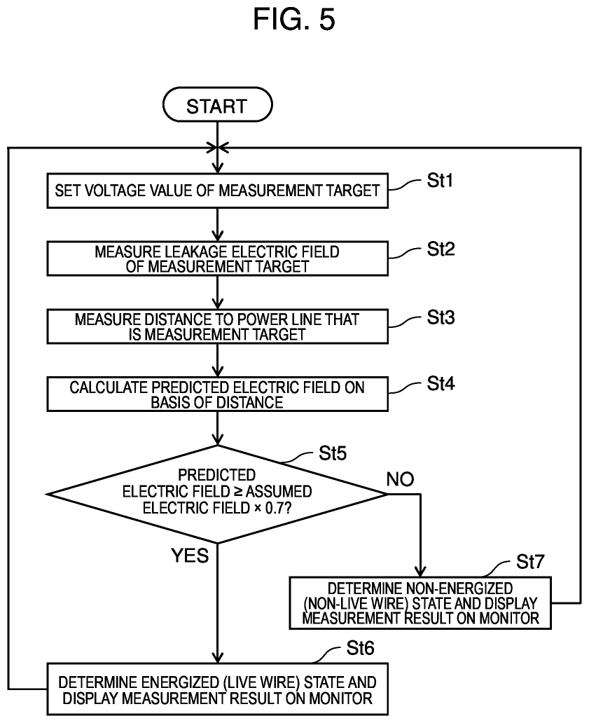

An operation procedure example of leakage electric field measurement device 100 according to Exemplary Embodiment 1 will be described with reference to FIG. 5. FIG. 5 is a flowchart illustrating an operation procedure example of leakage electric field measurement device 100 according to Exemplary Embodiment 1.

Input unit 15 accepts a user's input operation regarding a voltage value applied to a measurement target object. Input unit 15 outputs the input voltage value to processor 11. Processor 11 sets the voltage value input from input unit 15 as an assumed voltage of the measurement target object (SW.

Electric field sensor 24 receives (measures) an electric field leaking from the measurement target object located within an electric field reception region (that is, within a frame line (refer to FIGS. 6A and 6B)) in which the leakage electric field is received, and outputs the reception signal to signal processor 23 (St2). Signal processor 23 performs conversion into a signal indicating the leakage electric field intensity leaking from the measurement target object on the basis of the reception signal intensity received by electric field sensor 24. Signal processor 23 outputs a signal indicating the converted leakage electric field intensity to communicator 20. The output signal indicating the leakage electric field intensity is transmitted to processor 11 via communicator 20 and communicator 10. Processor 11 acquires the measurement electric field of the measurement target object on the basis of the leakage electric field intensity in a region of the electric field reception region (within the frame line) in the signal indicating the leakage electric field intensity.

Distance sensor 25 measures a distance to an electric wire that is the measurement target object located in the electric field reception region (that is, within the frame line (refer to FIGS. 6A and 6B)) in which the leakage electric field is received (St3). Distance sensor 25 outputs the measured distance to processor 21. The measured distance is transmitted to processor 11 via communicator 20 and communicator 10.

Processor 11 calculates a predicted electric field that is predicted to be leaking from the measurement target object on the basis of the measured measurement electric field and distance (St4).

Processor 11 refers to the electric field graph of the voltage corresponding to the assumed voltage set in the process in step St1, and calculates an assumed electric field of the measurement target object on the basis of the measured distance. Processor 11 compares the calculated assumed electric field with the predicted electric field, and determines whether or not the predicted electric field is 70% or more of the assumed electric field (St5).

In the process in step St5, in a case where the predicted electric field is 70% or more of the assumed electric field (St5, YES), processor 11 determines that the measurement target object is in a live wire (energized) state. Processor 11 generates a composite image in which the calculated assumed electric field, measurement results including the measured measurement electric field and distance, and a frame line indicating each measurement range are superimposed on the captured image, and outputs the composite image to monitor 14. Monitor 14 displays the output composite image (St6). Processor 11 may further generate an image, text, or voice for notifying the user that the measurement target object is in a live wire (energized) state as a measurement result, and output the image, the text, or the voice to monitor 14.

On the other hand, in the process in step St5, in a case where the predicted electric field is less than 70% of the assumed electric field (St5, NO), processor 11 determines that the measurement target object is in a non-live wire (stopped) state. Processor 11 generates a composite image in which the calculated assumed electric field, measurement results including the measured measurement electric field and distance, and a frame line indicating each measurement range are superimposed on the captured image, and outputs the composite image to monitor 14. Monitor 14 displays the output composite image (St7). Processor 11 may further generate an image, text, or voice for notifying the user that the measurement target object is in a non-live wire (stopped) state as a measurement result, and output the image, the text, or the voice to monitor 14.

Consequently, leakage electric field measurement device 100 according to Exemplary Embodiment 1 can determine whether or not the electric wire is in a live wire (energized) state.

The operation procedure example illustrated in FIG. 5 is an example and is not limited to this. For example, the procedure of the process executed in step St2 and the procedure of the process executed in step St3 may be reversed.

In the processes in step St5 and step St6, the measured value (numerical value) which is the measurement result of the leakage electric field intensity or the value of the predicted electric field may be superimposed on the captured image in correspondence to the position of the measurement target object, and the frame line may be omitted. The measured value or the predicted electric field value superimposed here is superimposed at a position near the measurement target object. Consequently, the user can check the position of the measurement target object and also check the measured value (numerical value) or the predicted electric field of the leakage electric field leaking from the measurement target object.

FIG. 6A is a diagram illustrating an example of composite image (live wire) Sr1. FIG. 6B is a diagram illustrating an example of composite image (non-live wire) Sr2. FIG. 6A illustrates an example in which, among plurality of electric wires PL1 and PL2, electric wire PL2 is used as a measurement target object, and whether or not electric wire PL2 is in a live wire (energized) state is measured by a user. FIG. 6B illustrates an example in which, among plurality of electric wires PL3 and PL4, electric wire PL4 is used as a measurement target object, and whether or not electric wire PL4 is in a live wire (energized) state is measured by the user.

Composite image Sr1 is generated in the process in step St6 in the operation procedure example of leakage electric field measurement device 100 described with reference to FIG. 5, and is displayed on monitor 14. Composite image Sr1 is generated including each of plurality of electric wires PL1 and PL2 captured in the captured image acquired by camera 13, and measurement result SS1 and frame line Ar1 superimposed by processor 11.

Measurement results SS1 including the assumed electric field (2000 V/m) input by the user, the leakage electric field (that is, the measurement electric field) (2000 V/m) of electric wire PL2 measured by electric field sensor 24, and the distance (1 m) to the electric wire PL2 measured by distance sensor 25 are superimposed on the captured image.

Frame line Ar1 indicates an electric field reception region of a leakage electric field in electric field sensor 24 and a measurable range of a distance in distance sensor 25. Frame line Ar1 in FIG. 6A indicates that the predicted electric field is 70% or more of the assumed electric field, that is, electric wire PL2 is in a live wire (energized) state, and thus the inside of the frame line is displayed to be filled with a color such as red. As for frame line Ar1, only a color of the frame line may be displayed red, for example.

Composite image Sr2 is generated in the process in step St7 in the operation procedure example of leakage electric field measurement device 100 described with reference to FIG. 5, and is displayed on monitor 14. Composite image Sr2 is generated including plurality of electric wires PL3 and PL4 captured in the captured image acquired by camera 13, and measurement results SS2 and frame line Ar2 superimposed by processor 11.

Measurement results SS2 including the assumed electric field (2000 V/m) input by the user, the leakage electric field (that is, the measurement electric field) (100 V/m) of electric wire P1A measured by electric field sensor 24, and the distance (1 m) to the electric wire P1A measured by distance sensor 25 are superimposed on the captured image.

Frame line Ar2 indicates an electric field reception region of a leakage electric field in electric field sensor 24 and a measurable range of a distance in distance sensor 25. Frame line Ar2 in FIG. 6B indicates that the predicted electric field is less than 70% of the assumed electric field, that is, electric wire PL2 is in a live wire (energized) state, and thus the inside of the frame line is displayed in a color such as blue or yellow. As for frame line Ar2, only the frame line may be displayed, for example, blue or yellow.

Each of composite images Sr1 and Sr2 illustrated in FIGS. 6A and 6B is an example and is not limited to this. Each of composite images Sr1 and Sr2 may be generated including an image, text information, or the like indicating whether or not a measurement target object is in a live wire (energized) state.

The measured value (numerical value) which is the measurement result of the leakage electric field intensity or the value of the predicted electric field may be superimposed on the captured image in correspondence to the position of the measurement target object, and the frame line may be omitted. The measured value or the predicted electric field value superimposed here is superimposed at a position near the measurement target object. Consequently, the user can check the position of the measurement target object and also check the measured value (numerical value) or the predicted electric field of the leakage electric field leaking from the measurement target object. As described above, in leakage electric field measurement device 100 according to

Exemplary Embodiment 1, whether or not an electric wire is in a live wire (energized) state can be visualized and presented to a user.

### Exemplary Embodiment 2

In leakage electric field measurement device 100 according to Exemplary Embodiment 1, a configuration example in which terminal device 1 and measurement unit 2 are separately provided has been described. In leakage electric field measurement device 200 according to Exemplary Embodiment 2, a configuration example in which terminal device 1 and measurement unit 2 are integrally provided will be described.

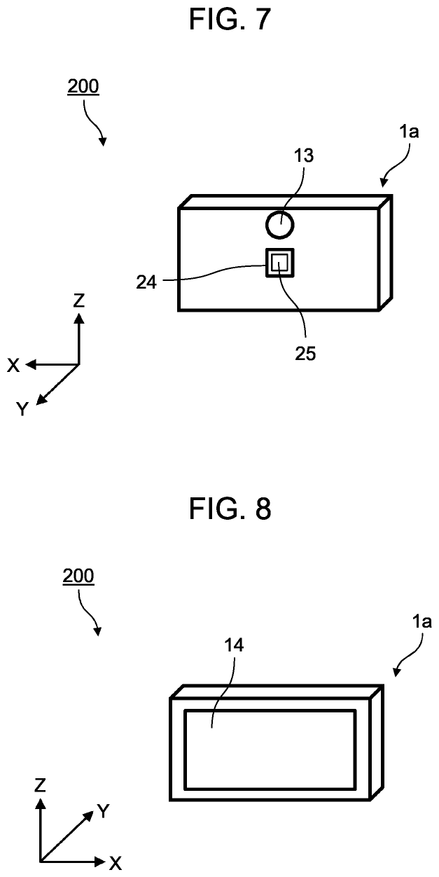

FIG. 7 is an appearance diagram illustrating an example of leakage electric field measurement device 200 (rear surface) according to Exemplary Embodiment 2. FIG. 8 is an appearance diagram illustrating an example of leakage electric field measurement device 200 (front surface) according to Exemplary Embodiment 2. Leakage electric field measurement device 200 according to Exemplary Embodiment 2 has substantially the same configuration as the configuration of leakage electric field measurement device 100 according to Exemplary Embodiment 1. Therefore, the same reference numerals are given to the same constituents as those in Exemplary Embodiment 1, and the description thereof will be omitted.

Leakage electric field measurement device 200 according to Exemplary Embodiment 2 includes electric field sensor 24 and distance sensor 25 on the rear surface side of terminal device la. In leakage electric field measurement device 200, an optical axis of camera 13, a central axis of a measurement range in which an intensity of a leakage electric field can be measured by electric field sensor 24 and which is perpendicular to the rear surface of terminal device la, and an optical axis of distance sensor 25 are disposed to be arranged in parallel to each other. In a case where camera 13 measures a distance to a measurement target object, distance sensor 25 may be omitted.

Consequently, an amount of misalignment (that is, an offset amount) between reference points in a captured image acquired by camera 13 and each of measurement results measured by electric field sensor 24 and distance sensor 25 is quantitatively reduced.

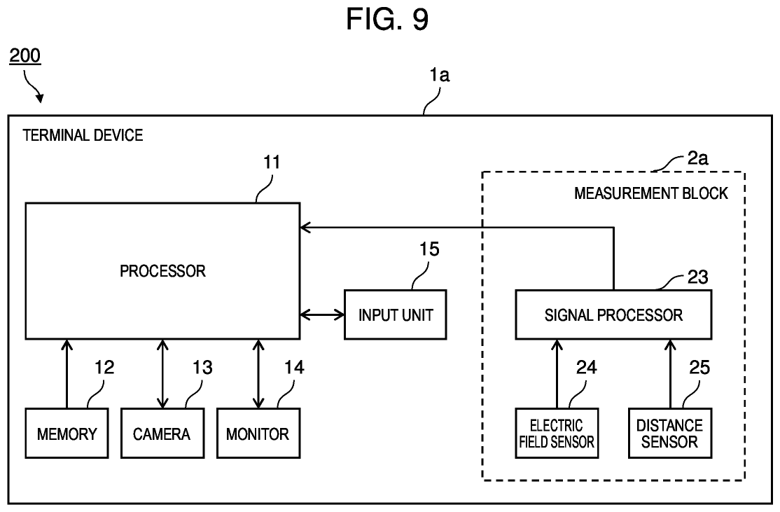

FIG. 9 is a block diagram illustrating an internal configuration example of leakage electric field measurement device 200 according to Exemplary Embodiment 2.

Measurement block 2a in Exemplary Embodiment 2 has substantially the same configuration as the internal configuration of measurement unit 2 in Exemplary Embodiment 1. Measurement block 2a is configured to include signal processor 23, electric field sensor 24, and distance sensor 25. A function of signal processor 23 may be realized by processor 11. Distance sensor 25 is not an essential constituent and may thus be omitted. In such a case, a function of distance sensor 25 may be realized by camera 13.

Processor 11 in Exemplary Embodiment 2 controls operations of terminal device 1a and each constituent of measurement block 2a provided in terminal device la. Processor 11 cooperates with memory 12 to perform various processes and control including measurement block 2a in an integrated manner. Specifically, processor 11 refers to a program and data stored in memory 12 and executes the program to realize a function of each constituent (for example, a function of measuring a leakage electric field with electric field sensor 24, a function of measuring a distance to a measurement target object and a direction of the measurement target object with distance sensor 25, a function of determining whether or not a measured leakage electric field exceeds a set threshold value, and a function of outputting a composite image in which a measurement result is superimposed on a captured image from camera 13 to monitor 14).

Memory 12 in Exemplary Embodiment 2 stores, for example, an offset amount based on an imaging region of camera 13, a measurable range of electric field sensor 24, and a reference position for measurement of distance sensor 25.

As described above, leakage electric field measurement device 200 according to Exemplary Embodiment 2 is formed as an integral body, and can visualize whether or not an electric wire is in a live wire (energized) state to a user. Leakage electric field measurement device 200 can minimize an offset amount between camera 13 and electric field sensor 24 and an offset amount between camera 13 and distance sensor 25. Therefore, when leakage electric field measurement device 200 can easily perform position alignment when measurement results measured by electric field sensor 24 and distance sensor 25 and a determination result of whether or not an electric wire is a live wire are superimposed on a captured image acquired by camera 13.

As described above, leakage electric field measurement devices 100 and 200 according to Exemplary Embodiments 1 and 2 include a controller that calculates a predicted value (predicted electric field) of a leakage electric field of an electric wire on the basis of a distance measured by a first acquirer that measures the distance to the electric wire (measurement target object) and a measurement result of the leakage electric field of the electric wire measured by a second acquirer that measures the leakage electric field, determines whether or not the electric wire is a live wire according to comparison between an assumed electric field of the electric wire and the predicted value, and generates a composite image in which a determination result is superimposed on a captured image acquired by a third acquirer that acquires the captured image of the electric wire.

Consequently, leakage electric field measurement devices 100 and 200 can visualize whether or not the electric wire is a live wire. Therefore, a user can easily check whether or not the electric wire is a live wire before starting work even if the electric wire that is a work target is in a live wire (energized) state due to an abnormality such as a connection failure of an apparatus.

The predicted value (predicted electric field) in leakage electric field measurement devices 100 and 200 according to Exemplary Embodiments 1 and 2 is calculated on the basis of the distance, the leakage electric field, and voltage values of one or more other electric wires adjacent to the electric wire. Consequently, leakage electric field measurement devices 100 and 200 can calculate the predicted value on the basis of the voltage values of one or more other electric wires adjacent to the electric wire (measurement target object). That is, even in a case where the second acquirer receives leakage electric fields leaking from one or more other adjacent electric wires, leakage electric field measurement devices 100 and 200 can estimate predicted electric fields or leakage electric fields of the other electric wires on the basis of the distance measured by the first acquirer and voltage values of the other electric wires. Therefore, leakage electric field measurement devices 100 and 200 can calculate the predicted value of the electric wire of which the user wants to check an energized state even in a case where there is another electric wire adjacent to the electric wire.

The controller of leakage electric field measurement devices 100 and 200 according to Exemplary Embodiments 1 and 2 calculates the predicted value (predicted electric field) by using a measurement result when the electric wire is located within a measurement range (electric field reception region) in which the second acquirer can measure the leakage electric field. Consequently, leakage electric field measurement devices 100 and 200 can determine whether or not the electric wire desired to be measured by the user is a live wire. Therefore, the user can check whether or not the electric wire is a live wire before starting work even if the electric wire that is a work target is in a live wire (energized) state due to an abnormality such as a connection failure of an apparatus.

The controller of leakage electric field measurement devices 100 and 200 according to Exemplary Embodiments 1 and 2 compares the assumed electric field with the predicted value (predicted electric field), and determines that the electric wire is not a live wire in a case where the predicted value is less than a predetermined ratio of the assumed electric field. Consequently, leakage electric field measurement devices 100 and 200 can determine whether or not the electric wire desired to be measured by the user is a live wire. Therefore, the user can recognize whether or not the electric wire is a live wire before starting work even if the electric wire that is a work target is in a live wire (energized) state due to an abnormality such as a connection failure of an apparatus.

In leakage electric field measurement devices 100 and 200 according to Exemplary Embodiments 1 and 2, the second acquirer measures a frequency of 50 Hz to 60 Hz. The leakage electric field at a frequency of 50 Hz to 60 Hz is highly distance-dependent. Therefore, leakage electric field measurement devices 100 and 200 can measure a leakage electric field leaking from an electric wire used for an indoor wiring, connection of electrical apparatuses, power transmission and distribution, or the like to which an AC voltage having the frequency of 50 Hz to 60 Hz is applied without receiving leakage electric fields with other frequencies, determine whether or not the measured electric wire is a live wire, and visualize a live wire (energized) state. Therefore, the user can recognize whether or not the electric wire is a live wire before starting work even if the electric wire that is a work target is in a live wire state due to an abnormality such as a connection failure of an apparatus.

The controller of leakage electric field measurement devices 100 and 200 according to Exemplary Embodiments 1 and 2 superimposes a predetermined color on the range measured by the second acquirer according to a result of the determination. Consequently, leakage electric field measurement devices 100 and 200 can visualize whether or not the electric wire in the measured range is in a live wire (energized) state to the user by using the color superimposed on the measured range. Therefore, the user can easily determine whether or not the measured electric wire is a live wire on the basis of the color of the measured range.

The controller of leakage electric field measurement devices 100 and 200 according to Exemplary Embodiments 1 and 2 superimposes a predetermined color on the electric wire imaged by the third acquirer according to a result of the determination. Leakage electric field measurement devices 100 and 200 can visualize whether or not the electric wire within the range measured by the user is in a live wire (energized) state by using the color superimposed on the electric wire. Therefore, the user can easily determine whether or not the measured electric wire is a live wire on the basis of the color of the electric wire.

Leakage electric field measurement devices 100 and 200 according to Exemplary Embodiments 1 and 2 include a fourth acquirer that receives input of the assumed electric field of the electric wire (measurement target object). The controller acquires the assumed electric field of the electric wire from the fourth acquirer. Consequently, leakage electric field measurement devices 100 and 200 can accept an input operation for the assumed electric field of the electric wire from the user, and thus the user can easily check an energized state of the electric wire on the basis of the input assumed electric field and the calculated predicted value (predicted electric field).

Leakage electric field measurement devices 100 and 200 according to Exemplary Embodiments 1 and 2 further include monitor 14 (output unit) that outputs the composite image generated by the controller. Consequently, leakage electric field measurement devices 100 and 200 can output the composite image in which the determination result is superimposed on the captured image acquired by the third acquirer to monitor 14. Therefore, the user can easily check an energized state of the electric wire by using the output composite image.

The second acquirer of leakage electric field measurement devices 100 and 200 according to Exemplary Embodiments 1 and 2 has a plurality of directional antennas. Consequently, leakage electric field measurement devices 100 and 200 can measure a leakage electric field from a predetermined direction and simultaneously measure leakage electric fields respectively leaking from a plurality of electric wires. Therefore, in a case where the user wants to simultaneously measure electric wires such as a single-phase two-wire system wire and a three-phase three-wire system wire, the user can recognize whether or not the electric wire is a live wire through one measurement.

In leakage electric field measurement device 200 according to Exemplary Embodiment 2, a measurement central axis of the second acquirer (specifically, a central axis of a measurement range in which an intensity of the leakage electric field can be measured by electric field sensor 24 and which is perpendicular to the rear surface of terminal device 1a) and an optical axis of the third acquirer are disposed to be arranged in parallel to each other. Consequently, leakage electric field measurement device 200 can minimize an offset amount between the third acquirer and the second acquirer, and can thus easily perform position alignment when the measurement result measured by the second acquirer and the result of the determination of whether or not the electric wire is a live wire are superimposed on the captured image acquired by the third acquirer.

Although various exemplary embodiments have been described above with reference to the accompanying drawings, the present disclosure is not limited to such examples. It is obvious that a person skilled in the art can conceive of various changes, modifications, replacements, additions, deletions, and equivalents within the category disclosed in the claims, and it is understood that they fall within the technical scope of the present disclosure. The respective constituents in the various exemplary embodiments described above may be freely combined within the scope without departing from the concept of the invention.

### INDUSTRIAL APPLICABILITY

The present disclosure is useful as a leakage electric field measurement device visualizing whether or not an electric wire is a live wire.

### REFERENCE MARKS IN THE DRAWINGS

1,1a Terminal device

2 Measurement unit

2a Measurement block

10, 20 Communicator

11, 21 Processor

12, 22 Memory

13 Camera

14 Monitor

15 Input unit

23 Signal processor

24 Electric field sensor

25 Distance sensor

100,200 Leakage electric field measurement device

GR assumed electric field graph

Ar1, Ar2 Frame line

Sr1, Sr2 Composite image

1. A leakage electric field measurement device comprising:
a first acquirer that measures a distance to an electric wire;
a second acquirer that measures a leakage electric field of the electric wire;
a third acquirer that acquires a captured image of the electric wire; and
a controller that calculates a predicted value of the leakage electric field of the electric wire on the basis of the distance measured by the first acquirer and the leakage electric field measured by the second acquirer, performs determination of whether or not the electric wire is a live wire according to comparison between an assumed electric field of the electric wire and the predicted value, and generates a composite image in which a result of the determination is superimposed on the captured image acquired by the third acquirer.

2. The leakage electric field measurement device according to claim 1, wherein the predicted value is calculated on the basis of the distance, the leakage electric field, and voltage values of one or more other electric wires adjacent to the electric wire.

3. The leakage electric field measurement device according to claim 1, wherein the controller calculates the predicted value by using the leakage electric field measured when the electric wire is located within a measurement range of the second acquirer.

4. The leakage electric field measurement device according to claim 1, wherein the controller compares the assumed electric field with the predicted value, and determines that the electric wire is not a live wire in a case where the predicted value is less than a predetermined ratio of the assumed electric field.

5. The leakage electric field measurement device according to claim 1, wherein the second acquirer measures a frequency of 50 Hz to 60 Hz.

6. The leakage electric field measurement device according to claim 1, wherein the controller superimposes a predetermined color on a range measured by the second acquirer according to a result of the determination.

7. The leakage electric field measurement device according to claim 1, wherein the controller superimposes a predetermined color on the electric wire imaged by the third acquirer according to a result of the determination.

8. The leakage electric field measurement device according to claim 1, further comprising a fourth acquirer that receives input of the assumed electric field of the electric wire,
wherein the controller acquires the assumed electric field of the electric wire from the fourth acquirer.

9. The leakage electric field measurement device according to claim 1, further comprising an output unit that outputs the composite image generated by the controller.

10. The leakage electric field measurement device according to claim 1, wherein the second acquirer has a plurality of directional antennas.

11. The leakage electric field measurement device according to claim 1, wherein a measurement central axis of the second acquirer and an optical axis of the third acquirer are disposed to be arranged in parallel to each other.
